(19) United States
(12) Patent Application Publication
(10) Pub. No.: US 2017/0194900 A1
(43) Pub. Date: Jul. 6, 2017

(54) METHODS FOR MOUNTING A JUNCTION BOX ON A GLASS SOLAR MODULE WITH CUTOUT

(71) Applicant: SolarCity Corporation, San Mateo, CA (US)

(72) Inventors: Christoph Erben, San Rafael, CA (US); Scott Tripp, San Rafael, CA (US)

(21) Appl. No.: 14/985,356

(22) Filed: Dec. 30, 2015

(51) Int. Cl. H02S 40/34; H01L 31/02; H01L 31/0224; H01L 31/048

(52) U.S. Cl. CPC H02S 40/34; H01L 31/0488; H01L 31/02013; H01L 31/022466

(57) ABSTRACT

A solar module assembly is provided that can include a framed solar panel. The panel may include bifacial solar cells, a front facing glass cover layer, and a back facing glass cover layer. A junction box may be mounted over the back facing glass cover layer. In particular, the back facing glass cover layer may have a cutout portion through which conductive leads connect to the bifacial solar cells and the junction box. The cutout portion may be formed along an edge or a corner of the back facing glass cover layer. The frame may have a first flange member that extends at least partially over the junction box and a second flange member that extends over the front facing glass layer. The junction box and the frame may be attached to the solar panel and hermetically sealed using silicone adhesive material, for example.

### BACKGROUND

Field

This is related to the fabrication of solar cells, including bifacial tunneling junction solar cells.

Related Art

The negative environmental impact of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi junction structure includes multiple single-junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit.

FIG. 1 shows a diagram of conventional solar cell 100. Solar cell 100 includes n-type doped Si substrate 102, p⁺ silicon emitter layer 104, front electrode grid 106, and Aluminum (Al) back electrode 108. Arrows in FIG. 1 indicate incident sunlight. As shown in FIG. 1, Al back electrode 108 covers the entire backside of solar cell 100, hence preventing light absorption at the backside. Moreover, front electrode grid 106 often includes a metal grid that is opaque to sunlight and casts a shadow on the front surface of solar cell 100. For conventional solar cell 100, the front electrode grid can block up to 8% of the incident sunlight, thus significantly reducing the conversion efficiency.

### SUMMARY

In one embodiment, a solar module assembly is provided. The assembly can include a solar panel having a front facing glass cover layer, a back facing glass cover layer, and a plurality of bifacial solar cells encapsulated between the front and back facing glass cover layers. The back facing glass cover layer may be provided with an edge cutout portion. A junction box may be mounted directly over the edge cutout portion. One or more conductive leads may protrude through the edge cutout portion to connect the solar cells to the junction box.

A metal frame that at least partially surrounds the solar panel may be attached to the solar panel. In a variation on the embodiment, the metal frame may include a first flange (lip) member that extends at least partially over the junction box and a second flange (lip) member that extends at least partially over the front facing glass cover layer. Adhesive material (e.g., silicon adhesive) may be formed between the frame and the solar panel and may be cured to hermetically seal the solar module assembly.

A corner cutout portion may be formed in the back facing glass cover layer. In general, one or more cutout portions may be formed along any edge or corner of the solar panel. Each cutout portion may have an oval shape, an elliptical shape, a rectangular shape, a triangular shape, or any other suitable shape. A separate junction box may be formed over each cutout portion.

Further features of the invention, its nature and various advantages will be more apparent from the accompanying drawings and following detailed description.

### BRIEF DESCRIPTION OF THE FIGURES

FIG. 1 shows a cross-sectional side view of a conventional solar cell.

FIG. 2 shows a cross-sectional side view of an illustrative double-sided tunneling junction solar cell in accordance with an embodiment of the present invention.

FIG. 3A shows a top view illustrating the electrode grid of a conventional solar cell.

FIG. 3B shows a top view illustrating the front or back surface of an exemplary bifacial solar cell with a single center busbar for each surface in accordance with an embodiment of the present invention.

FIG. 3C shows a cross-sectional side view of an illustrative bifacial solar cell with a single center busbar on each of the front and back surfaces in accordance with an embodiment of the present invention.

FIG. 3D is a diagram showing the front surface of an exemplary bifacial solar cell in accordance with an embodiment of the present invention.

FIG. 3E is a diagram showing the back surface of an exemplary bifacial solar cell in accordance with an embodiment of the present invention.

FIG. 3F shows a cross-sectional side view of an exemplary bifacial solar cell with a single edge busbar on each of the top and bottom surfaces in accordance with an embodiment of the present invention.

FIG. 4A is a diagram of an exemplary solar panel that includes a plurality of solar cells with a single busbar at the center in accordance with an embodiment of the present invention.

FIG. 4B is a diagram of an exemplary solar panel that includes a plurality of solar cells with a single busbar at the edge in accordance with an embodiment of the present invention.

FIG. 4C is a diagram of an illustrative solar panel having input-output leads coupled to a junction box in accordance with an embodiment of the present invention.

FIG. 5A is a cross-sectional side view of a glass-glass solar module with through-holes for the junction box leads.

FIG. 5B is a bottom view showing two through-holes in the back glass layer of FIG. 5A.

FIG. 6A is a bottom view of an illustrative back glass layer with a cutout portion in accordance with an embodiment of the present invention.

FIG. 6B is a diagram showing busbar leads that are exposed in the cutout portion in accordance with an embodiment of the present invention.

FIG. 6C is a diagram showing a junction box being mounted over the cutout portion in accordance with an embodiment of the present invention.

FIG. 6D is a cross-sectional side view showing how the junction box may be mounted directly over the cutout portion and sealed to a frame structure in accordance with an embodiment of the present invention.

FIG. 6E is an exploded perspective view showing how the glass-glass solar module of FIG. 6D may be attached to the frame structure in accordance with an embodiment of the present invention.

FIG. 6F is a bottom view showing how the junction box may be at least partially tucked under the frame structure in accordance with an embodiment of the present invention.

FIGS. 6G-6J show how one or more cutout portions may be formed along any edge or corner of the back glass layer in accordance with some embodiments of the present invention.

FIGS. 6K-6M show how each edge cutout region may have any suitable shape in accordance with some embodiments of the present invention.

FIGS. 6N-6P show how each corner cutout region may have any suitable shape in accordance with some embodiments of the present invention.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a high-efficiency solar module, sometimes referred to as a solar “panel.” State of the art solar panels sometimes have bifacial solar cells having top and bottom surfaces that are sensitive to incoming light. To take advantage of the bifacial sensitivity, solar panels may have translucent (e.g., glass) covers formed on the top and bottom sides of the panel. When both covers are made from glass, the solar panels may be referred to as “glass-glass” solar modules.

Each solar panel may be coupled to a corresponding junction box. The junction box may, for example, have current bypass diodes, electrostatic discharge protection diodes, or other suitable electrical components. The solar cells may be coupled to the junction box via one or more conductive leads. In one suitable approach, the leads may protrude from the glass edge and the junction box may be mounted over the edge of the glass. In another suitable approach, one or more through-holes may be drilled in the back glass layer so that the conductive leads may be threaded through the drilled holes. In accordance with some embodiments of the present invention, one or more cutout regions may be formed at the edges and/or corners of the back glass layer to help expose the conductive leads and to enable subsequent connection by mounting the junction box directly over the cutout regions. The junction box may have an edge flange that is aligned to the glass edge. A frame can then be applied over the glass layer and the junction box flange and sealed using adhesive material.

### Bifacial Tunneling Junction Solar Cells

FIG. 2 shows an exemplary double-sided tunneling junction solar cell. Double-sided tunneling junction solar cell 200 can include substrate 202, quantum tunneling barrier (QTB) layers 204 and 206 covering both surfaces of substrate 202 and passivating the surface-defect states, a front-side doped a-Si layer forming front emitter 208, back-side doped a-Si layer forming back surface field (BSF) layer 210, front transparent conducting oxide (TCO) layer 212, back TCO layer 214, front metal grid 216, and back metal grid 218. Note that it is also possible to have the emitter layer at the backside and a front surface field (FSF) layer at the front side of the solar cell. Details, including fabrication methods, about double-sided tunneling junction solar cell 200 can be found in U.S. patent application Ser. No. 12/945,792 (Attorney Docket No. SSP10-1002US), entitled “Solar Cell with Oxide Tunneling Junctions,” by inventors Jiunn Benjamin Heng, Chentao Yu, Zheng Xu, and Jianming Fu, filed 12 Nov. 2010, the disclosure of which is incorporated by reference in its entirety herein.

As shown in FIG. 2, the symmetric structure of double-sided tunneling junction solar cell 200 ensures that double-sided tunneling junction solar cell 200 can be bifacial given that the backside is exposed to light. In solar cells, the metallic contacts, such as front and back metal grids 216 and 218, are necessary to collect the current generated by the solar cell. In general, a metal grid includes two types of metal lines, including busbars and fingers. More specifically, busbars are wider metal strips that are connected directly to external leads (such as metal tabs), while fingers are finer areas of metallization which collect current for delivery to the busbars. The key design trade-off in the metal grid design is the balance between the increased resistive losses associated with a widely spaced grid and the increased reflection and shading effect caused by a high fraction of metal coverage of the surface.

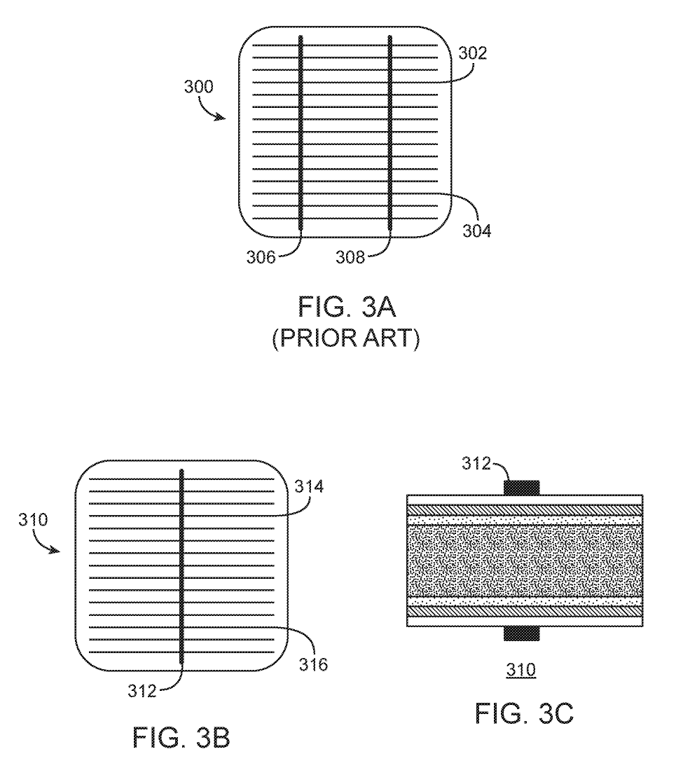

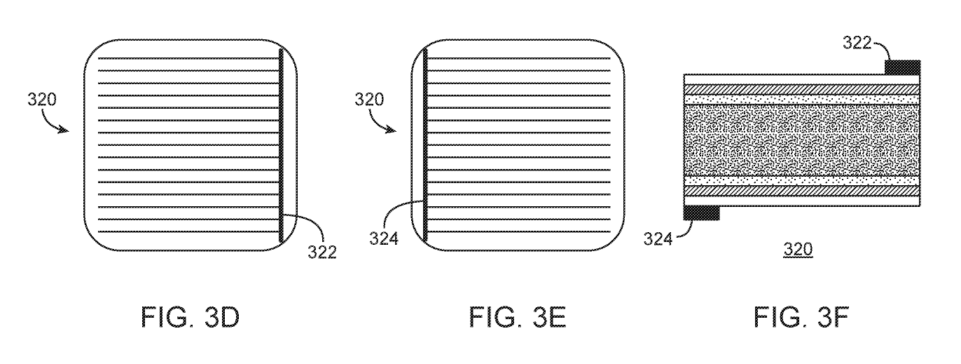

In conventional solar cells, to prevent power loss due to series resistance of the fingers, at least two busbars are placed on the surface of the solar cell to collect current from the fingers, as shown in FIG. 3A. For standardized 5-inch solar cells (which can be 5×5 inch² squares or pseudo squares with beveled corners), there are typically two busbars at each surface. For larger, 6-inch solar cells (which can be 6×6 inch² squares or pseudo squares), three or more busbars may be needed depending on the resistivity of the electrode materials. Note that in FIG. 3A a surface (which can be the front or back surface) of solar cell 300 can include a plurality of parallel finger lines, such as finger lines 302 and 304, and two busbars 306 and 308 placed perpendicular to the finger lines. Note that the busbars are placed in such a way as to ensure that the distance (and hence the resistance) from any point on a finger to a busbar is small enough to minimize power loss. However, these two busbars and the metal ribbons that are later soldered onto these busbars for inter-cell connections can create a significant amount of shading, which degrades the solar cell performance.

In some embodiments, the front and back metal grids, such as the finger lines, can include electroplated Cu lines, which have reduced resistance compared with conventional Ag grids. For example, using an electroplating or electroless plating technique, one can obtain Cu grid lines with a resistivity of equal to or less than 5×10⁻⁶ Ω·cm. Details about an electroplated Cu grid can be found in U.S. patent application Ser. No. 12/835,670 (Attorney Docket No. SSP10-1001US), entitled “Solar Cell with Metal Grid Fabricated by Electroplating,” by inventors Jianming Fu, Zheng Xu, Chentao Yu, and Jiunn Benjamin Heng, filed 13 Jul. 2010; and U.S. patent application Ser. No. 13/220,532 (Attorney Docket No. SSP10-1010US), entitled “Solar Cell with Electroplated Metal Grid,” by Jianming Fu, Jiunn Benjamin Heng, Zheng Xu, and Chentao Yu, filed 29 Aug. 2011, the disclosures of which are incorporated by reference in their entireties herein.

The reduced resistance of the Cu fingers makes it possible to have a metal grid design that maximizes the overall solar cell efficiency by reducing the number of busbars on the solar cell surface. In some embodiments of the present invention, a single busbar is used to collect finger current. The power loss caused by the increased distance from the fingers to the busbar can be balanced by the reduced shading.

FIG. 3B shows the front or back surface of an exemplary bifacial solar cell with a single center busbar per surface, in accordance with an embodiment of the present invention. In FIG. 3B, the front or back surface of solar cell 310 can includes single busbar 312 and a number of finger lines, such as finger lines 314 and 316.

FIG. 3C shows a cross-sectional view of the bifacial solar cell with a single center busbar per surface, in accordance with an embodiment of the present invention. The semiconductor multilayer structure shown in FIG. 3C can be similar to the one shown in FIG. 2, for example. Note that the finger lines are not shown in FIG. 3C because the cut plane cuts between two finger lines. In the example shown in FIG. 3C, busbar 312 runs in and out of the paper, and the finger lines run from left to right. As discussed previously, because there is only one busbar at each surface, the distances from the edges of the fingers to the busbar are longer. However, the elimination of one busbar reduces shading, which not only compensates for the power loss caused by the increased finger-to-busbar distance, but also provides additional power gain. For a standard sized solar cell, replacing two busbars with a single busbar in the center of the cell can produce a 1.8% power gain.

FIG. 3D shows the front surface of an exemplary bifacial solar cell, in accordance with an embodiment of the present invention. In FIG. 3D, the front surface of solar cell 320 includes a number of horizontal finger lines and vertical single busbar 322, which is placed at the right edge of solar cell 320. More specifically, busbar 322 is in contact with the rightmost edge of all the finger lines, and collects current from all the finger lines.

FIG. 3E presents a diagram illustrating the back surface of an exemplary bifacial solar cell, in accordance with an embodiment of the present invention. In FIG. 3E, the back surface of solar cell 320 includes a number of horizontal finger lines and a vertical single busbar 324, which is placed at the left edge of solar cell 320. Similar to busbar 322, single busbar 324 is in contact with the leftmost edge of all the finger lines. FIG. 3F presents a diagram illustrating a cross-sectional side view of the bifacial solar cell with a single edge busbar per surface, in accordance with an embodiment of the present invention. The semiconductor multilayer structure shown in FIG. 3F can be similar to the one shown in FIG. 2. Like FIG. 3C, in FIG. 3F, the finger lines (not shown) run from left to right, and the busbars run in and out of the paper. From FIGS. 3D-3F, one can see that in this embodiment, the busbars on the front and the back surfaces of the bifacial solar cell are placed at the opposite edges of the cell. This configuration can further improve power gain because the busbar-induced shading now occurs at locations that were less effective in energy production. In general, the edge-busbar configuration can provide at least a 2.1% power gain.

Note that the single busbar per surface configurations (either the center busbar or the edge busbar) not only can provide power gain, but also can reduce fabrication cost, because less metal will be needed for busing ribbons. Moreover, in some embodiments of the present invention, the metal grid on the front sun-facing surface can include parallel metal lines (such as fingers), each having a cross-section with a curved parameter to ensure that incident sunlight on these metal lines is reflected onto the front surface of the solar cell, thus further reducing shading. Such a shade-free front electrode can be achieved by electroplating Ag- or Sn-coated Cu, or the like, using a well-controlled, cost-effective patterning scheme.

### Solar Module Layout

Multiple solar cells with a single busbar (either at the cell center or the cell edge) per surface can be assembled to form a solar module or panel via a typical panel fabrication process with minor modifications. Based on the locations of the busbars, different modifications to the stringing/tabbing process are needed. In conventional solar module fabrications, the double-busbar solar cells are strung together using two stringing ribbons (also called tabbing ribbons) which are soldered onto the busbars. More specifically, the stringing ribbons weave from the front surface of one cell to the back surface of the adjacent cell to connect the cells in series. For the single busbar in the cell center configuration, the stringing process is very similar, except that only one stringing ribbon is needed to weave from the front surface of one cell to the back surface of the other.

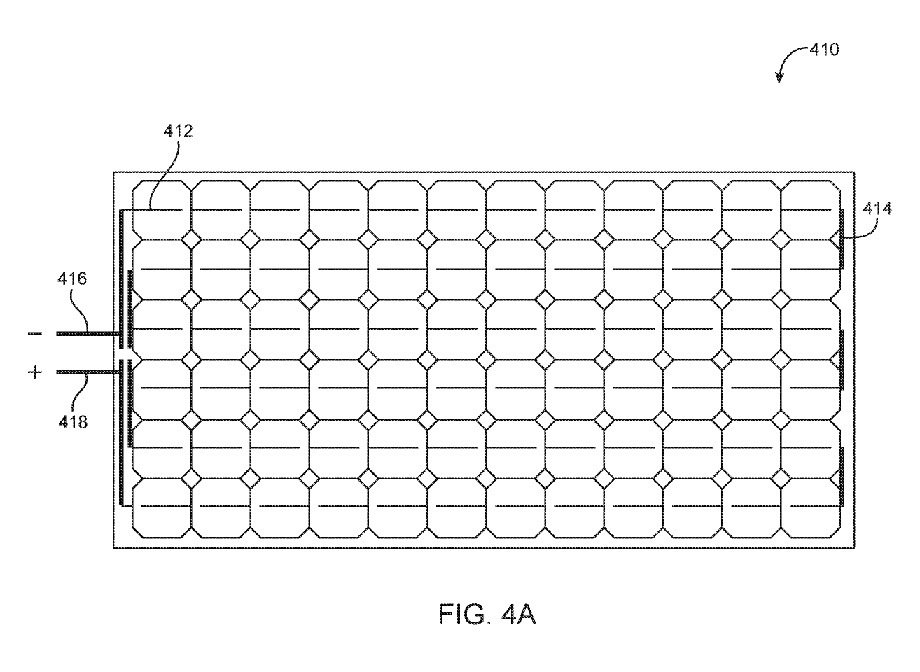

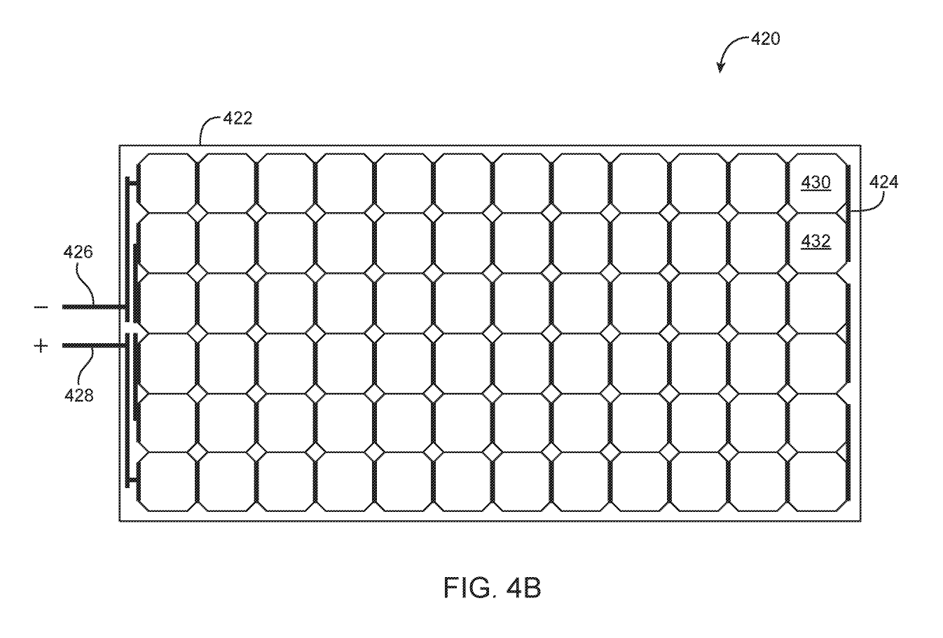

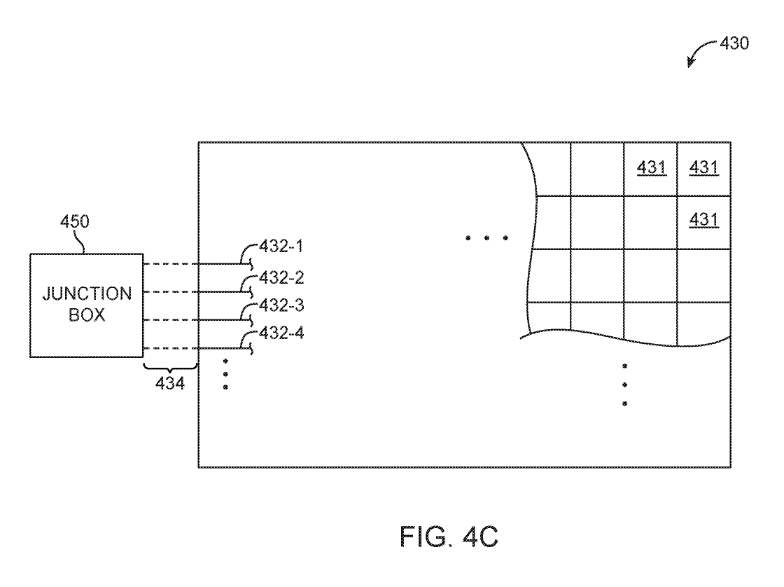

FIG. 4A shows an exemplary solar panel that can include a plurality of solar cells with a single busbar at the center, in accordance with an embodiment of the present invention. Solar panel 410 can include a 6×12 array of solar cells. Adjacent solar cells in a row can be connected in series to each other via a single stringing ribbon, such as ribbon 412. The single stringing ribbons at the ends of adjacent rows are joined together by a wider bus ribbon, such as bus ribbon 414. In the example shown in FIG. 4A, the rows are connected in series. In practice, the solar cell rows can be connected in parallel as well. The finger lines run perpendicular to the direction of the solar cell row (and hence the stringing ribbons) and are not shown in FIG. 4A so as to not unnecessarily obscure the present embodiments.

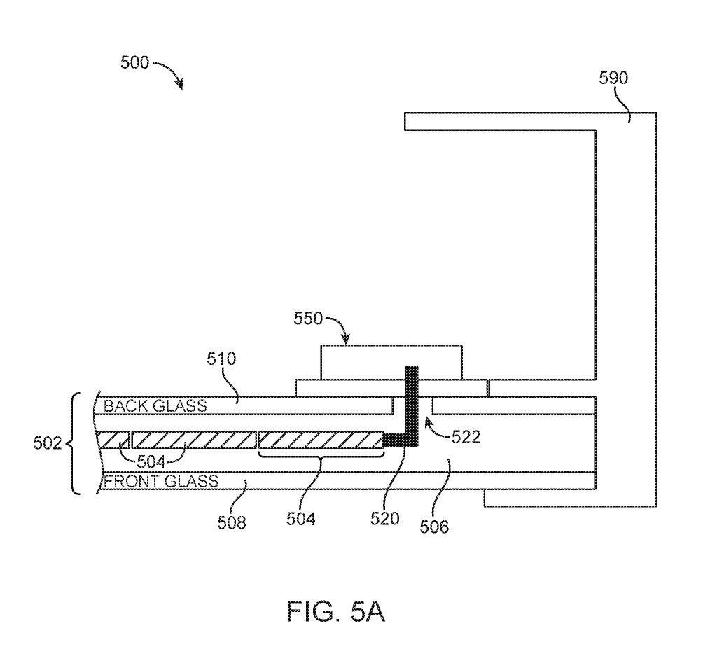

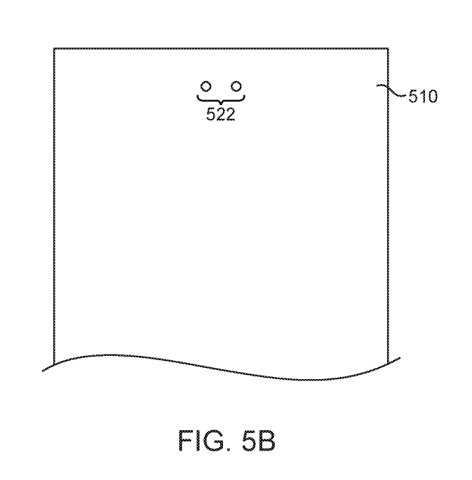

FIG. 4B shows an exemplary solar panel that can include a plurality of solar cells with a single busbar at the edge. In FIG. 4B, solar panel 420 includes a 6×12 array of solar cells. Solar cells in a row are connected in series to each other either via a single tab, such as a tab 422, or by edge-overlapping in a shingled pattern. At the end of the row, instead of using a wider bus ribbon to connect stringing ribbons from adjacent cells together (like the example shown in FIG. 4A), here we simply use a tab that is sufficiently wide to extend through edges of both end cells of the adjacent rows. For example, extra-wide tab 424 can extend through edges of cells 430 and 432. For serial connection, extra-wide tab 424 can connect the busbar at the top surface of cell 430 with the busbar at the bottom surface of cell 432, which means solar cells 430 and 432 can be placed in such a way that the top edge busbar of cell 430 aligns with the bottom edge busbar of cell 432. Note that if the solar cells in a row are placed in a shingled pattern, the adjacent rows may have opposite shingle patterns, such as right-side on top or left-side on top. For parallel connection, extra-wide tab 430 may connect both the top/bottom busbars of cells 430 and 432. If the solar cells in a row are shingled, the shingle pattern of all rows remains the same. Unlike the example shown in FIG. 4A, in FIG. 5J the finger lines (not shown) run along the direction of the solar cell rows.

The examples shown in FIGS. 4A and 4B are merely illustrative and are not intended to limit the scope of the present invention. In general, a solar module may include any number of solar cell strings coupled in series and/or parallel, where the busbars in each solar cell are coupled to one another using any suitable conductive routing or stacking arrangement. In general, each solar module may have a first input-output (IO) terminal that serves as a negative IO port and a second input-output terminal that serves as a positive IO port. In the example of FIG. 4A, the solar cells of module 410 can be coupled between negative port 416 and positive port 418. In the example shown in FIG. 4B, the solar cells of module 420 may be coupled between negative port 426 and positive port 428.

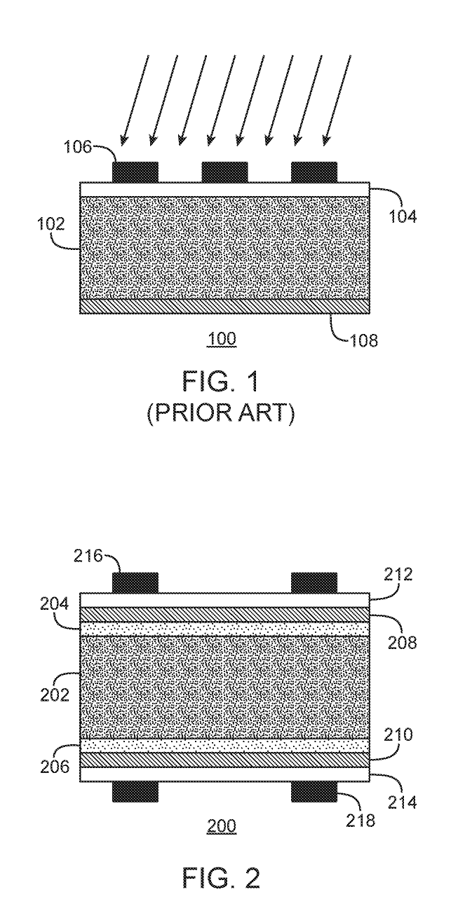

FIG. 4C shows a generic solar panel layout, where solar panel 430 can include an array of solar cells 431 coupled to a junction box, such as junction box 450 via conductive leads 434. The terms solar “panel” and solar “module” may sometimes be used interchangeably. Solar cells 431 may be any type of solar cell such as those described in connection with FIGS. 1-3. Junction box 450 may include any number of bypass diode components that are coupled to solar cells 431 and may serve as an interface to an array inverter, which is configured to convert the DC current output from panel 430 to AC current.

In the example shown in FIG. 4C, solar panel 430 is coupled to junction box 450 via four conductive wires 432-1, 432-2, 432-3, and 432-4. These conductive wires 432 (sometimes referred to as “leads”) may be coupled to at least some of the solar panel busbars to help provide the desired amount of connectivity to one or more internal nodes in the solar panel. In general, at least a first of conductive leads 434 may serve as a positive IO port while a second of leads 434 may serve as a negative IO port. The exemplary configuration of FIG. 4C, in which panel 430 is coupled to junction box 450 via four conductive leads, is merely illustrative. If desired, solar panel 430 may be coupled to junction box 450 via at least two conductive leads, at least three conductive leads, more than four conductive leads, eight or more conductive leads, etc.

### Junction Box Mounting

As described above, solar modules sometimes include bifacial tunneling junction solar cells. To enable absorption of light from both top and bottom surfaces, a solar module may be provided with glass cover layers on both front and back surfaces of the solar module. FIG. 5A shows an example of solar module assembly 500 that can include solar panel 502 attached to frame 590. Metal frame 590, for example, may be formed from aluminum, copper, steel, or any another suitable conductive/framing material.

As shown in FIG. 5A, panel 502 may include an array of bifacial solar cells 504 suspended in encapsulation material 506 between front facing glass 508 and back facing glass 510. Panel 502, which can have glass cover layers 508 and 510, is sometimes referred to herein as a “glass-glass” solar panel. Junction box 550 may be mounted on back glass 510. To provide connectivity between the solar cells 504 within panel 502 and junction box 550, conductive leads may be used to connect one or more busbars within solar panel 502 to junction box 550.

In the arrangement shown in FIG. 5A, drill holes such as drill hole 522 may be formed through back glass 510. FIG. 5B is a back view showing an example where two drill holes 522 are formed through back glass layer 510. Referring back to FIG. 5A, junction box 550 may be mounted over the drill holes 522 and the conductive leads such as conductive lead 520 may extend through hole 522 to connect junction box 550 to the solar cells 504. In some embodiments, glass cover layers 510 and 508 may be constructed using tempered glass. One potential drawback to this approach is that drilling holes through tempered glass may be prohibitively time consuming and costly.

Another way of ensuring electrical connectivity to the junction box through the glass cover layer involves forming conductive leads that protrude from the edge of the panel. The junction box can then be mounted over the edge of the panel, and an electrical connective can be made without having to drills holes through glass layer 510. This approach, however, obstructs attachment of metal frame 590 (i.e., a junction box mounted to the glass edge would prevent application of the aluminum frame). It would therefore be desirable to provide an improved glass-glass solar module assembly that enables connectivity to the back-side mounted junction box without having to drill holes while enabling application of the metal assembly frame.

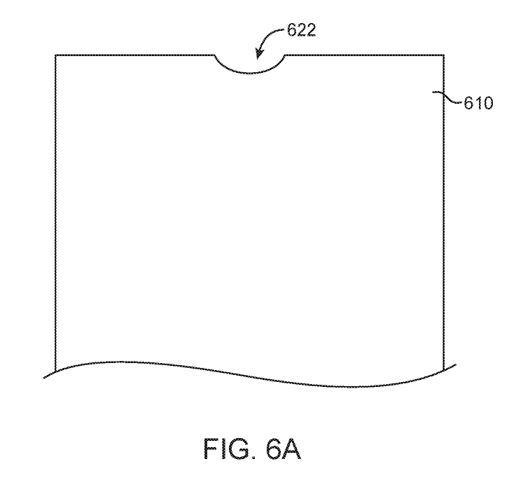

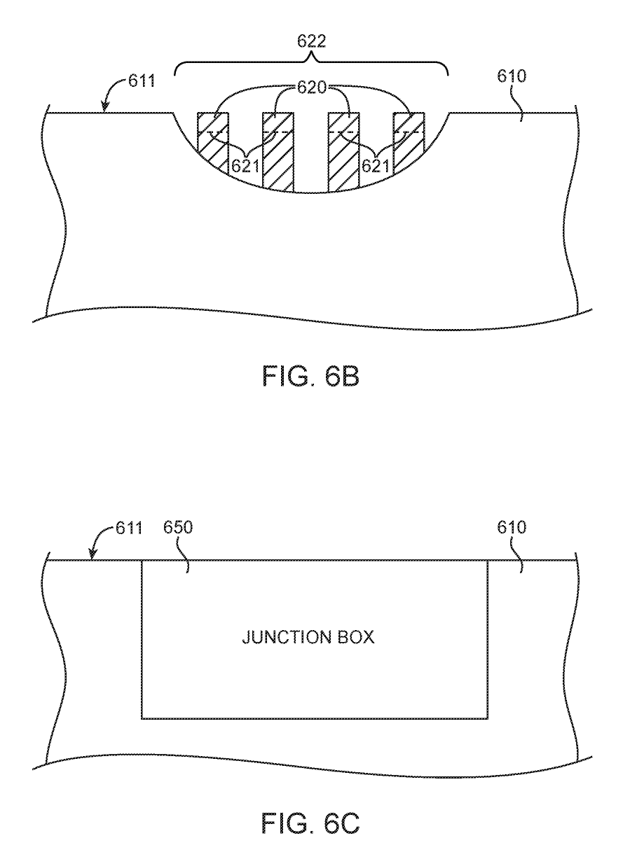

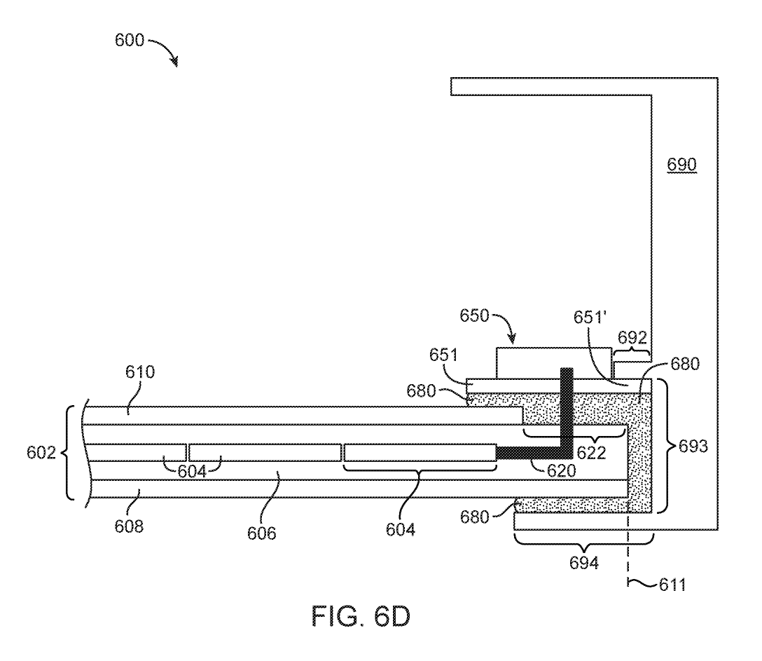

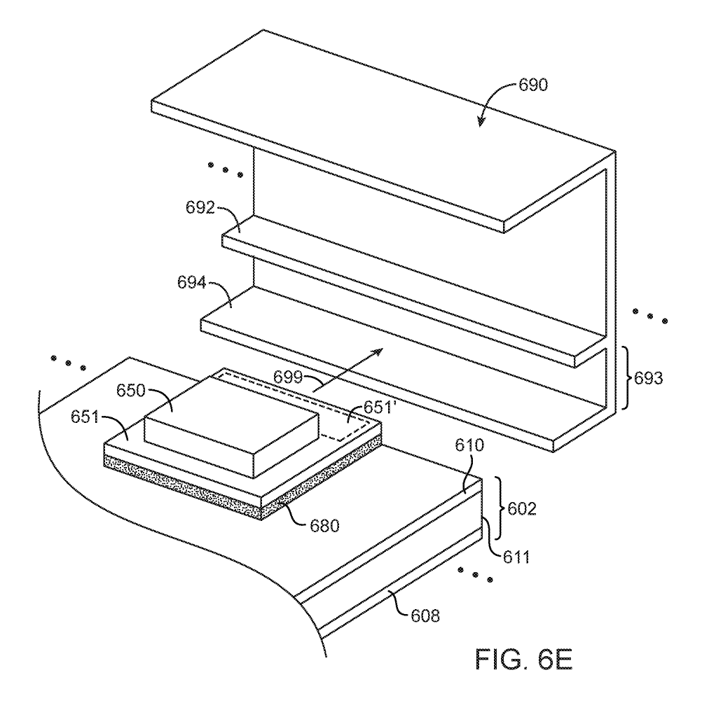

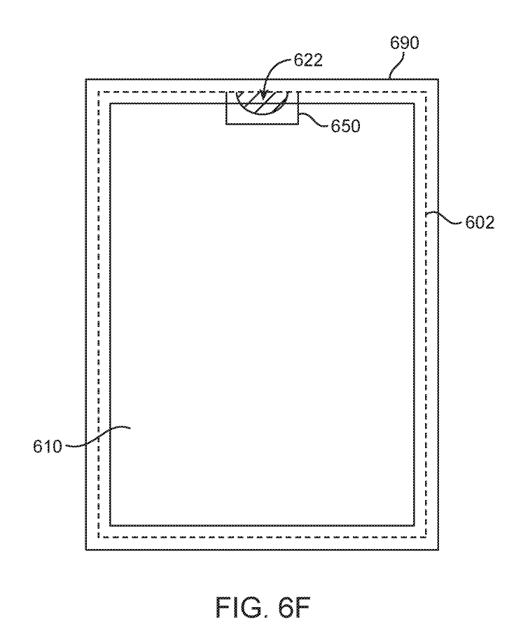

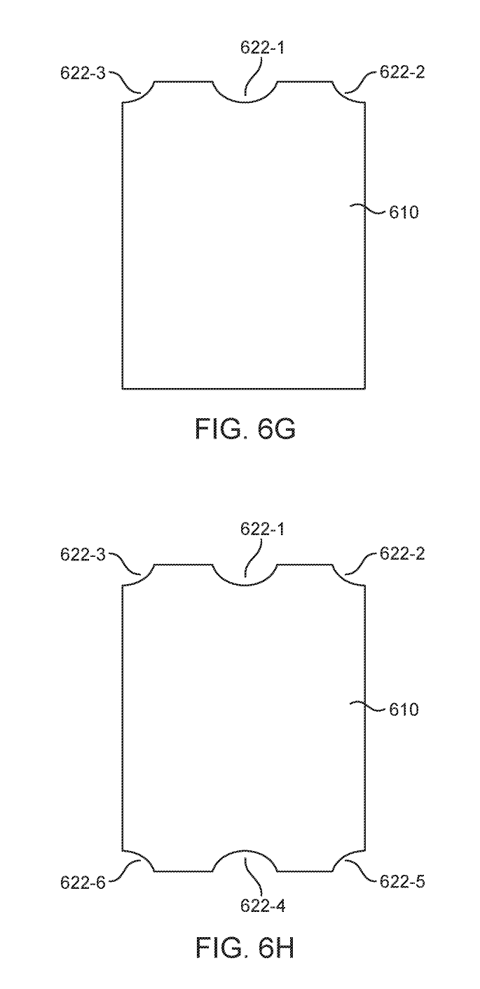

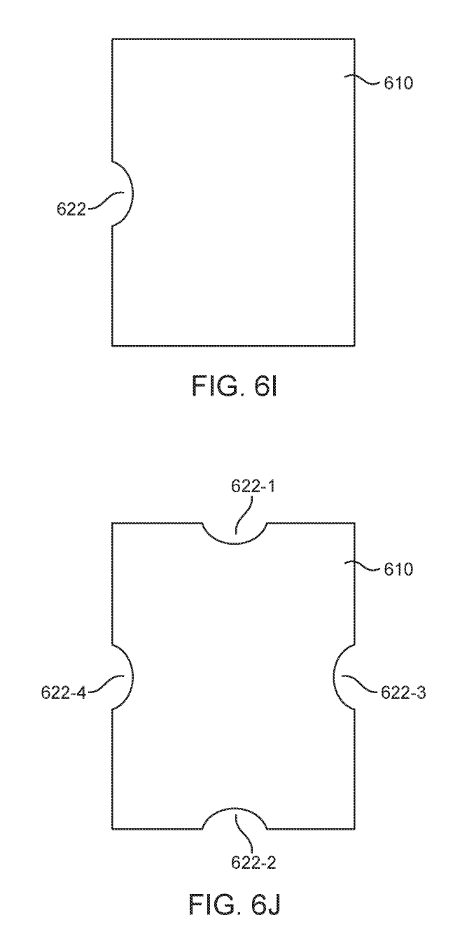

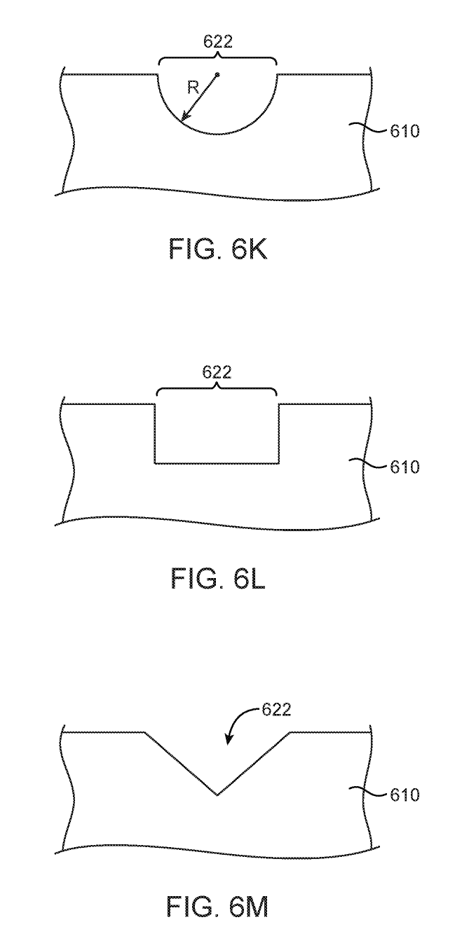

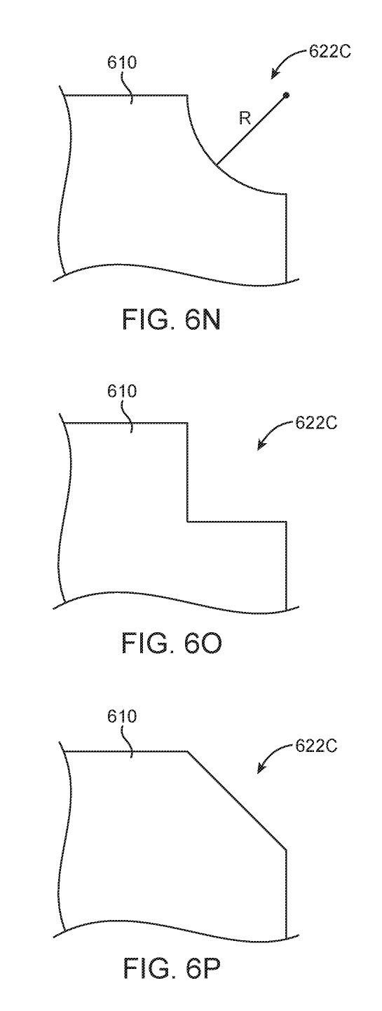

In accordance with an embodiment of the present invention, a glass-glass solar panel may be formed to include an edge cutout portion to expose underlying conductive leads so that electrical connections can be readily established to the exposed conductive leads. FIG. 6A is a bottom view of an illustrative back glass layer 610 with a cutout portion 622 in accordance with an embodiment of the present invention. Cutout portion 622 (or region) may, for example, be formed by an edge grinding or milling process that is substantially faster and cheaper than drilling holes. As an example, a through hole formed by drilling may have an effective cost of $1 USD whereas cutout region 622 may only have an effective cost of ¢10 USD or less.

Moreover, each cutout region 622 may accommodate protrusion of two or more conductive leads while each drill hole may only accommodate a single conductive lead. For example, consider a scenario in which five conductive leads need to be separately connected to a junction box. Using the back glass drill-hole approach, five individual holes may have to be formed, resulting in a total cost of $5 USD. In comparison, formation of a single cutout region 622 can expose all five conductive leads for a substantially lower cost of ¢10 USD.

FIG. 6B is a diagram showing four conductive leads 620 that are exposed in the cutout portion 622 in accordance with an embodiment of the present invention. As shown in FIG. 6B, conductive leads 620 may extend all the way to edge 611 of back surface glass layer 610. This need not be the case. If desired, the conductive leads (sometimes referred to as junction box leads) may extend at least some distance away from edge 611, as shown by dotted lines 621. The example of FIG. 6B in which four junction box leads 620 are exposed within region 622 is merely illustrative. If desired, cutout region 622 may have any suitable size to enable connection with any number of junction box leads (e.g., two or more leads, three or more leads, five or more leads, etc.).

FIG. 6C is a diagram showing a junction box 650 being mounted over cutout portion 622. As shown in FIG. 6C, junction box 650 may be mounted directly over region 622 and also mounted all the way to the edge 611 of the solar panel. When mounted, one or more passive components in junction box 650 (e.g., current bypass diodes) and input-output ports may be coupled to the appropriate conductive leads 620 to enable proper solar module functionality. Configured in this way, shading of the panel by junction box 650 is minimized and can help improve overall efficiency.

FIG. 6D is a cross-sectional side view showing how junction box 650 may be mounted directly over the cutout portion and sealed to a frame structure 690. As shown in FIG. 6D, solar module assembly 600 may include a solar panel 602 that is attached to a metal frame 690. Metal frame 690 (sometimes referred to as a solar panel bracket) may be formed from aluminum, copper, steel, or another suitable conductive/framing material.

Panel 602 may include an array of bifacial solar cells 604 suspended in encapsulation material 606 between front facing glass 608 and a back facing glass 610 (e.g., panel 602 is a glass-glass solar module). Junction box 650 may be mounted over back glass 610. To provide connectivity between the solar cells 604 within panel 602 and junction box 650, conductive leads 620 may be used to connect one or more busbars within solar panel 602 to junction box 650.

In particular, junction box 650 may be mounted directly over edge cutout portion 622 in back facing glass cover layer 610. One or more conductive leads 620 may extend into region 622 and protrude through glass layer 610 to make electrical contact with junction box 650. Junction box 650 may also have a flange (or base) 651. Frame 690 may have a first flange (or planar lip) member 692, a second flange (or planar lip) member 694, and a web portion 693 extending between the first and second flange members 692 and 694. First flange member 692, web portion 693, and second flange member 694 may form a track for receiving an edge of solar panel 602.

When frame 690 is attached to solar panel 602, first flange member 692 of frame 690 may be formed directly on portion 651′ of junction box flange 651 (e.g., first flange member 692 may extend over flange base portion 651′). Second flange member 694 may extend over front facing glass layer 608. The example of FIG. 6D in which junction box flange base portion 651′ extends beyond the edge 611 of panel 602 is merely illustrative. If desired, flange base portion 651′ may be aligned to the glass edge 611. In yet other suitable arrangements, flange base portion 651′ may be mounted some distance away from edge 611.

Still referring to FIG. 6D, adhesive material 680 may be dispensed between junction box 650 and solar panel 602 and between solar panel 602 and frame 690 to hermetically seal solar module assembly 600. Adhesive material 680 may be silicone adhesives, epoxy, resin, moisture and light curable adhesives, pressure sensitive adhesives, or other suitable types of adhesive or sealant/molding material. Sealing glass-glass solar module 600 in this way can help provide enhanced resistance to moisture penetration and reliability.

FIG. 6E is an exploded perspective view showing how glass-glass solar panel 602 of FIG. 6D may be attached to frame 690 in accordance with an embodiment of the present invention. As shown in FIG. 6E, adhesive material 680 may be used to mount junction box 650 on back glass layer 610. After junction box 650 has been mounted on panel 602, the partial assembly may then be inserted into the track portion of frame 690, as indicated by the direction of arrow 699. For example, panel edge 611 may be brought towards web portion 693 of frame 690 so that flange member 692 extends over flange base portion 651 (as indicated by the dotted region in FIG. 6E) and so that flange member 694 extends under front glass layer 608. Once solar panel 602 has been properly inserted into frame 690, additional adhesive material 680 may be applied and cured to complete the sealing process.

FIG. 6F is a bottom view showing how metal frame 690 may be attached to each edge of solar panel 602 (e.g., frame 690 may completely surround solar panel 602). Frame 690 may help provide structural support and also a grounding path for the entire solar module assembly. In other words, adhesive material 680 may also be dispensed along each edge of solar panel 602 to help provide proper sealing.

As shown in FIG. 6F, junction box 650 may be at least partially tucked under the frame structure. Forming junction box 650 as close to the panel edge as possible may help minimize any undesired shading caused by the mounting of junction box 650 from the back side. If desired, junction box 650 may also be mounted at one or more corners of panel 650 to further minimize shading.

The example of FIG. 6F in which metal frame 690 is formed along every edge of solar panel 602 is merely illustrative. In other suitable embodiments, the metal frame may be attached to only three sides of the solar panel, to only two adjacent sides of the solar panel, to only two opposing edges of the solar panel, to only one edge of the solar panel, etc.

FIGS. 6G-6J are bottom views showing how one or more cutout portions may be formed along any edge or corner of the back glass layer in accordance with some embodiments of the present invention. As shown in FIG. 6G, a first cutout portion 622-1 may be formed at the center of the top edge of back glass layer 610; a second cutout portion 622-2 may be formed at the top right corner of layer 610; and a third cutout portion 622-3 may be formed at the top left corner of layer 610. If desired, a fourth cutout portion 622-4 may be formed at the center of the bottom edge of back glass layer 610; a fifth cutout portion 622-5 may be formed at the bottom right corner of layer 610; and a sixth cutout portion 622-6 may be formed at the bottom left corner of layer 610 (see, e.g., FIG. 6H).

In accordance with another suitable embodiment as shown in FIG. 6I, cutout portion 622 may be formed at the center of the left edge of back glass layer 610. In accordance with yet another suitable embodiment as shown in FIG. 6J, a different cutout portion may be formed at the center of each edge of glass layer 610 (e.g., a first cutout region 622-1 may be formed at the center of the top edge of glass 610; a second cutout region 622-2 may be formed at the center of the bottom edge of glass 610; a third cutout region 622-3 may be formed at the center of the right edge of glass 610; a fourth cutout region 622-4 may be formed at the center of the left edge of glass 610).

The exemplary embodiments of FIGS. 6G-6J are merely illustrative and are not intended to limit the scope of the present invention. In general, any number of cutout portions may be formed along any edge or corner of back glass layer 610, where each cutout portion exposes one or more junction box leads. A junction box may be mounted over each respective cutout region 622 to make an electrical connection to the underlying junction box lead(s). If desired, front facing glass layer 608 may also be provided with one or more cutout portions so that a junction box can be mounted to the front side of the solar module.

In the examples above, each cutout region 622 has an oval or elliptical shape. This is merely illustrative. In general, each cutout portion may have any suitable shape. FIG. 6K shows an edge cutout region 622 having a semi-circular shape with a radius R. FIG. 6L shows an edge cutout region 622 with a rectangular shape. FIG. 6M shows an edge cutout region 622 having a triangular shape. If desired, each cutout region 622 may have any shape that is easy and cost-effective to manufacture.

The corner cutout regions may also have any suitable shape that is easy and cost-effective to manufacture. FIG. 6N shows a corner cutout region 622C having a circular shape with a radius R. FIG. 6O shows a corner cutout region 622C having a square shape or rectangular shape. FIG. 6P shows a corner cutout region 622C having a triangular shape. These examples are also merely illustrative and do not limit the scope of the present invention. In general, the size and shape of each cutout portion may depend on the number of underlying conductive leads that need to be exposed and also the shape of the junction box being mounted over that cutout portion.

The foregoing is merely illustrative of the principles of this invention and various modifications can be made by those skilled in the art without departing from the scope and spirit of the invention. The foregoing embodiments may be implemented individually or in any combination. Additionally, the above disclosure is not intended to limit the present invention.

What is claimed is:

1. A solar module assembly comprising:
a front facing glass cover layer;
a back facing glass cover layer having a cutout portion;
a plurality of solar cells interposed between the front and back facing glass cover layers; and
a junction box mounted over the cutout portion of the back facing glass cover layer.

2. The solar module assembly of claim 1, wherein the cutout portion is formed along an edge of the back facing glass cover layer.

3. The solar module assembly of claim 1, wherein the cutout portion is formed at a corner of the back facing glass cover layer.

4. The solar module assembly of claim 1, further comprising:
a conductive lead that extends through the cutout portion and that electrically connects the plurality of solar cells to the junction box.

5. The solar module assembly of claim 1, further comprising:
a metal frame that at least partially surrounds the solar module assembly.

6. The solar module assembly of claim 5, wherein the metal frame includes a first flange member that extends over the junction box and a second flange member that extends over the front facing glass cover layer.

7. The solar module assembly of claim 6, further comprising:
adhesive material formed between the metal frame and the front facing glass cover layer and between the junction box and the metal frame.

8. The solar module assembly of claim 1, wherein the plurality of solar cells comprises an array of bifacial tunneling junction solar cells.

9. A method for manufacturing a solar module assembly, comprising:
encapsulating a plurality of solar cells between a front facing glass cover layer and a back facing glass cover layer to form a solar panel;
coupling a conductive lead that to the plurality of solar cells such that it extends through an edge cutout portion of the back facing glass cover layer; and
mounting a junction box directly over the edge cutout portion of the back facing glass cover layer.

10. The method of claim 9, further comprising:
coupling an additional conductive lead to the plurality of solar cells such that it also extends through the edge cutout portion of the back facing glass cover layer.

11. The method of claim 9, wherein the edge cutout portion is formed via an edge milling process.

12. The method of claim 9, further comprising:
attaching a frame to the solar panel, wherein the frame has a first flange member that extends at least partially over the junction box and a second flange member that extends at least partially over the front facing glass cover layer.

13. The method of claim 12, further comprising:
dispensing adhesive material between the frame and the solar panel; and
curing the adhesive material.

14. The method of claim 9, further comprising:
forming another edge cutout portion in the back facing glass cover layer; and
mounting an additional junction box over the another edge cutout portion.

15. The method of claim 9, further comprising:
forming a corner cutout portion in the back facing glass cover layer; and
mounting an additional junction box over the corner cutout portion.

16. An apparatus comprising:
a solar panel that includes:
a plurality of bifacial tunneling junction solar cells;
a first glass layer; and
a second glass layer, wherein the plurality of bifacial tunneling junction solar cells are interposed between the first and second glass layers, and wherein the second glass layer has an edge cutout region; and
a junction box mounted directly over the edge cutout region, wherein the junction box is coupled to the plurality of bifacial tunneling junction solar cells via conductive leads that protrude through the edge cutout region.

17. The apparatus of claim 16, wherein the junction box has a flange base portion.

18. The apparatus of claim 17, further comprising:
a conductive frame that is attached to the solar panel, wherein the conductive frame has a first lip portion that extends over the flange base portion of the junction box and a second lip portion that extends over the first glass layer.

19. The apparatus of claim 18, further comprising:
silicon adhesive material that seals the solar panel to the conductive frame.

20. The apparatus of claim 16, wherein the edge cutout region is formed at an edge of the second glass layer, and wherein the junction box is flush with the edge of the second glass layer.
